(19) United States
(12) Patent Application Publication
(10) Pub. No.: US 2024/0375202 A1
(43) Pub. Date: Nov. 14, 2024

(54) FLUXING CALIBRATION

(71) Applicant: Illinois Tool Works Inc., Glenview, IL (US)

(72) Inventors: Gerardus Johannes Adrianus Maria DIEPSTRATEN, Dongen (NL); Antonie Cornelis COLIJN, Nieuwendijk (NL)

(21) Appl. No.: 18/576,889

(22) PCT Filed: Jul. 1, 2022
(86) PCT No.: PCT/US2022/035977

§ 371 Date: Jan. 5, 2024

(30) Foreign Application Priority Data
Jul. 6, 2021 (EP) 21184040.0

(51) Int. Cl. B23K 1/20; B23K 3/08

(52) U.S. Cl. CPC B23K 1/203; B23K 3/082

(57) ABSTRACT

Example methods of calibrating a parameter in a fluxing process in a soldering machine involve: determining an expected flux result when at least one calibration flux setting is used to spray flux from a nozzle; spraying flux from the nozzle using the at least one calibration flux setting; measuring the obtained flux result when flux is sprayed using the at least one calibration flux setting; calculating the difference between the measured obtained flux result and the expected flux result; and calculating a flux result correction factor corresponding to the at least one calibration flux setting, wherein the flux result correction factor is applicable to the soldering machine during a fluxing process, to reduce the difference between the sprayed flux result and the expected flux result.

### TECHNICAL FIELD

The disclosure relates to the application of flux to circuit boards. In particular, the disclosure relates to calibrating the application of flux.

### BACKGROUND

Selective soldering machines are used to solder electronics components to boards, such as to printed circuit boards (PCBs). The boards pass through the machine and undergo a soldering process to connect the components to the board. The soldering process typically includes the application of flux to the joints between the components and the board, pre-heating the components and the board, and applying solder to the connections between the components and the board.

To control the soldering process a program is produced and provided to the soldering machine. This program contains information relating to the locations of the solder joints on the board as well as the required machine settings, including the required machine settings for applying flux to the board.

Software is used to generate the program. The software interrogates a flux library to determine the solid content of the flux per unit area when applied, from data in the library pertaining to the flux density, flux spreading and solid content. Typically, maximum and minimum values of solid content per square inch are set in the program and the colour of the flux is inspected to check that the value is within the predefined range. However, no inspection of the solid content value occurs during the soldering process.

Flux is typically applied to the board using a high-frequency dropjet, or nozzle. The amount of flux applied is typically influenced by the open time of the dropjet; the frequency with which the dropjet is opened; the speed with which the dropjet is moved or the amount of time that the dropjet is held stationary while flux is applied; and the pressure on the tank which contains the flux. The amount of flux applied to the board is usually measured, or inferred, using a flow meter. If too much or too little flux is applied, then this may trigger an alarm. Sometimes, if the amount of flux measured differs from a setpoint value, a correction will be applied to the next board, the correction typically being implemented by altering the open time of the dropjet. However, this means that a whole board may have an incorrect amount of flux applied. Furthermore, this process can lead to long dropjet open times when, for example, the dropjet is blocked or worn. This can also lead to unnecessary wear of the dropjet, for example if open times are increased due to a blockage. This increases the likelihood of a sudden flooding of flux if a blockage clears.

It is also known to measure the amount of flux applied and flow direction of the applied flux, using a laser fork. However, using a laser fork only provides an estimate of the amount, and direction of flux, and does not provide a measurement of the flux on the board. For example, if the flux is sprayed at a non-perpendicular angle to the board, then the laser fork cannot quantify the actual location of the flux on the board to determine if this is acceptable. It is known to overcome this problem using a flux sensor, which comprises two conductive pads. The correct flux spray location is between the conductive pads, and when flux is sprayed with minimal deviation, the flux bridges the two conductive pads and completes an electrical circuit. This provides confirmation that the flux deviation is within predetermined boundaries. However, this method provides no quantification of the deviation of the flux spray. Furthermore, if any corrections are made, these are typically via manual intervention.

### SUMMARY

According to one example, there is provided a method of calibrating a parameter in a fluxing process in a soldering machine, the method comprising the steps of:
determining an expected flux result when at least one calibration flux setting is used to spray flux from a nozzle;
spraying flux from the nozzle using the at least one calibration flux setting;
measuring the obtained flux result when flux is sprayed using the at least one calibration flux setting;
calculating the difference between the measured obtained flux result and the expected flux result; and
calculating a flux result correction factor corresponding to the at least one calibration flux setting, wherein the flux result correction factor is applicable to the soldering machine during a fluxing process, to reduce the difference between the sprayed flux result and the expected flux result.

The soldering machine may be a selective soldering machine.

The at least one calibration flux setting may comprise or be at least one calibration flux amount setting. The parameter may comprise or be an amount of flux sprayed by a nozzle. The expected flux result may comprise or be an expected flux amount. The obtained flux result may comprise or be an amount of flux sprayed. The flux result correction factor may comprise or be a flux amount correction factor corresponding to the at least one calibration flux amount setting. The flux amount correction factor may be applicable to the soldering machine during a fluxing process, to reduce the difference between the sprayed amount of flux and the expected amount of flux.

The at least one calibration flux amount setting may comprise or be at least one calibration open time setting. The calibration open time setting may define the duration for which the nozzle is open.

The correction factor may be applied or be applicable to an operational open time of the nozzle during the fluxing process.

The at least one calibration flux amount setting may comprise or be at least one calibration flux tank pressure setting, the flux tank containing the flux which is fed to the nozzle.

The flux amount correction factor may be applied or be applicable to an operational flux tank pressure during a fluxing process, the flux tank containing the flux which is fed to the nozzle.

The amount of flux sprayed from the nozzle may be measured by measuring the amount of flux spreading onto a surface onto which the flux is sprayed. The amount of flux spreading may be measured using an optical device, for example a camera.

The optical device may view a surface opposite to the surface onto which flux is sprayed.

The amount of flux sprayed from the nozzle may be measured using an optical sensor. The optical sensor may comprise at least one laser fork sensor. The optical sensor may comprise at least one high-speed camera. The at least one high-speed sensor may be configured such that the frequency of flux droplets sprayed from the nozzle is measured or is measurable. The at least one high-speed sensor may be configured such that a dimension of each droplet is measured or is measurable. The dimension of each droplet may be measured via an estimation based upon a measurable dimension of the droplet. The dimension of each droplet may be measured via two or more high-speed cameras.

Determining an expected flux amount to be sprayed from the nozzle may be via a formula, algorithm or a lookup table. The flux amount correction factor may be stored in a lookup table corresponding to the calibration flux amount setting and/or to the expected amount of flux.

The at least one calibration flux amount setting may comprise or be a plurality of calibration flux amount settings.

The at least one calibration flux setting may comprise or be a nozzle location, such that flux sprayed onto a surface by the nozzle when the nozzle is located at the nozzle location is expected to have a centre at the expected spray location. The parameter may comprise or be a direction of flux sprayed by the nozzle. The expected flux result may comprise or be the expected spray location. The obtained flux result may comprise or be an actual spray location, which is measured by locating the centre of the sprayed flux on the surface. The flux result correction factor may comprise or be at least one position correction factor, wherein the position correction factor is applied or is applicable to the nozzle location during a fluxing process to reduce the difference between the expected spray location and the actual spray location.

Measuring the actual spray location may be via an optical device, for example a camera. The optical device may view a surface onto which flux is sprayed. The optical device may measure the centre of the flux on the surface to determine the location of the sprayed flux.

The method of calibrating the direction of flux may be performed with a plurality of nozzle open times. The method of calibrating the direction of flux may be performed with a plurality of nozzle opening frequencies. The method of calibrating the direction of flux may be performed with a plurality of flux tank pressure settings. The at least one position correction factor may be stored with corresponding nozzle open times and/or nozzle opening frequencies and/or flux tank pressure settings.

According to another example, there is provided a method of calibrating a nozzle for use in a fluxing process in a soldering machine, the method comprising the steps of:
calibrating the amount of flux sprayed by a nozzle using the aforementioned method; and
calibrating the direction of flux sprayed by a nozzle using the aforementioned method.

The soldering machine may be a selective soldering machine.

Any of the aforementioned methods may be controlled by calibration circuitry. The calibration circuitry may be a part of soldering machine control circuitry. Any measured, determined, or calculated parameters in any of the aforementioned methods may be stored, or recorded, in the calibration circuitry. The calibration circuitry may perform any of the aforementioned calculations. The calibration circuitry may be interactive, for example a user may input and output information to and from the calibration circuitry. The calibration circuitry may comprise processing circuitry. The calibration circuitry may comprise memory circuitry. The processing circuitry may process machine readable instructions. The machine-readable instructions may be stored in the memory circuitry. The machine-readable instructions may be uploaded, by a user, to the memory or processing circuitry. Any number of the sensors or devices may communicate with the calibration circuitry.

The surface may be absorbent. The surface may be transparent. The surface may be translucent. The surface may be of any suitable material. The surface may be paper.

The actual spray location may be measured using an optical device. The optical device may be a camera. The optical device may communicate with the calibration circuitry.

The actual spray location may be located by measuring the deviation of spray from the nozzle using at least two high-speed cameras. The at least two high-speed cameras may be located at oblique angles to one another.

According to another example there is provided a method of monitoring the performance of a soldering machine, the method comprising monitoring any of the aforementioned correction factors.

An alert or alarm may be provided if the amount of flux sprayed is below or above predefined thresholds. An alert or alarm may be provided if the direction of flux sprayed is outside of predefined bounds. An alert or alarm may be provided if the amount of flux spreading is below or above predefined thresholds.

The at least one flux amount correction factor may be used to determine if the nozzle requires maintenance or cleaning. Alternatively, or additionally, the at least one position correction factor may be used to determine if the nozzle requires maintenance and/or cleaning. Alternatively, or additionally, the amount of flux spreading may be used to determine if the nozzle requires maintenance and/or cleaning.

Maintenance may include cleaning. Maintenance may include repair. Maintenance may include replacement.

Maintenance may be required if the at least one flux amount correction factor increases more than a predefined amount. Maintenance may be required if the position correction factor increases more than a predefined amount.

Maintenance or cleaning may include performing a cleaning routine with the nozzle. The cleaning routine may comprise spraying flux from the nozzle at varying opening frequency. Alternately, or additionally, the cleaning routine may include applying cleaning alcohol to the nozzle.

The method of monitoring performance may be performed using the calibration circuitry. The method of monitoring performance may be performed automatically.

According to another aspect of the disclosure there is provided a flux nozzle calibration apparatus for calibrating a parameter of a flux nozzle, the flux nozzle being for use in a soldering machine, the apparatus comprising:
at least one sensor configured to measure an obtained flux result when flux is sprayed from a nozzle using at least one calibration flux setting;
processing circuitry configured to:
calculate the difference between the measured obtained flux result and an expected flux result; and
calculate a flux result correction factor corresponding to the at least one calibration flux setting, wherein the flux result correction factor is applicable to the soldering machine during a fluxing process, to reduce the difference between the sprayed flux result and the expected flux result.

The flux nozzle calibration apparatus may further comprise memory circuitry configured to store any number of:
the parameter of a flux nozzle:
the measured obtained flux result;
the expected flux result;
the at least one calibration flux setting; and
the flux result correction factor corresponding to the at least one calibration flux setting.

The flux nozzle calibration apparatus may further comprise a calibration surface which is configured to receive the flux which is sprayed from the nozzle.

The flux nozzle calibration apparatus may further comprise an optical device. The optical device may comprise a camera. He optical device may be configured to capture an image of the calibration surface. The image of the calibration surface may be used by the processing circuitry to calculate the difference between the measured flux result and the expected flux result. The memory circuitry may be configured to store the image of the calibration surface.

The calibration surface may be at least semi-transparent and/or at least partially absorbent of flux. The calibration surface may comprise paper. The calibration surface may comprise heat resistant paper. In use, flux may be sprayed onto a first side of the calibration surface. The optical device may be located facing a second side of the calibration surface. The optical device may capture an image of the second side of the surface to measure the obtained flux result when flux is sprayed using the at least one calibration flux setting.

The flux nozzle calibration apparatus may further comprise the nozzle. The flux nozzle calibration apparatus may further comprise a flux tank which contains the flux which is fed to the nozzle, in use.

The at least one calibration flux setting may comprise or be at least one calibration flux amount setting. The parameter may comprise or be an amount of flux sprayed by the nozzle, in use. The expected flux result may comprise or be an expected flux amount. The obtained flux result may comprise or be an amount of flux sprayed. The flux result correction factor may be a flux amount correction factor corresponding to the at least one calibration flux amount setting, wherein the correction factor is applicable to the soldering machine during a fluxing process, to reduce the difference between the sprayed amount of flux and the expected amount of flux.

The flux nozzle calibration apparatus may further comprise a high-speed camera. The high-speed camera may be configured to capture images of the flux as it is sprayed from the nozzle to obtain the amount of flux sprayed. The memory circuitry may be configured to store the images captured using the high-speed camera. The flux nozzle calibration apparatus may further comprise a plurality of high-speed cameras. The plurality of high-speed cameras may be configured to capture images of the flux as it is sprayed from the nozzle to obtain the amount of flux sprayed. The memory circuitry may be configured to store the images captured using the plurality of high-speed cameras. The captured images may be used by the processing circuitry to determine the frequency with which droplets of flux are sprayed form the nozzle. The measured amount of flux may be based upon an estimated size of the droplets of flux sprayed form the nozzle and the measured spray frequency. The size of each droplet may be estimated in part based upon a measured dimension of each droplet from the measurements obtained from the captured images. The memory circuitry may be configured to store any number of the aforementioned measurements.

The at least one calibration flux amount setting may comprise or be at least one calibration open time setting, the open time setting defining the duration for which the nozzle is open, in use.

The flux amount correction factor may be applied or may be applicable to an operational open time of the nozzle during the fluxing process.

The at least one calibration flux amount setting may comprise or be at least one calibration flux tank pressure setting.

The at least one calibration flux amount setting may comprise or be at least one calibration flux tank pressure setting.

The flux amount correction factor may be applied or may be applicable to an operational flux tank pressure during the fluxing process.

The amount of flux sprayed from the nozzle may be measured or may be measurable by measuring the amount of flux spreading onto the calibration surface. The amount of flux spreading may be measured using the optical device.

The at least one calibration flux setting may comprise or be a nozzle location, such that flux sprayed onto the calibration surface by the nozzle when the nozzle is located at the nozzle location is expected to have a centre at an expected spray location. The parameter may comprise or be a direction of flux sprayed by the nozzle. The expected flux result may comprise or be the expected spray location. The obtained flux result may comprise or be an actual spray location, which is measured by locating the centre of the sprayed flux on the surface. The flux result correction factor may comprise or be at least one position correction factor. The at least one position correction factor may be applied or may be applicable to the nozzle location during a fluxing process to reduce the difference between the expected spray location and the actual spray location.

The actual spray location may be located or may be locatable using the optical device.

The flux nozzle calibration apparatus may further comprise a plurality of high-speed cameras. The plurality of high-speed cameras may be located at oblique angles to one another. The plurality of high-speed cameras may be configured to capture images of the flux which is sprayed from the nozzle. The memory circuitry may be configured to store the images captured using the plurality of high-speed cameras. The processing circuitry may be configured to measure the angle of flux sprayed from the nozzle, from the captured images.

According to another aspect of the disclosure there is provided a soldering machine comprising the aforementioned flux nozzle calibration apparatus. The soldering machine may be a selective soldering machine.

### BRIEF DESCRIPTION OF DRAWINGS

Example embodiment(s) of the disclosure are illustrated in the accompanying drawings, in which:

FIG. 1 illustrates a method of calibrating an amount of flux sprayed by a nozzle in a fluxing process;

FIG. 2 illustrates an example of apparatus used to calibrate an amount of flux sprayed by a nozzle in a fluxing process;

FIG. 3 illustrates a method of calibrating a direction of flux sprayed by a nozzle in a fluxing process;

FIG. 4 illustrates a first example of apparatus used to calibrate a direction of flux sprayed from a nozzle in a fluxing process;

FIG. 5 illustrates a second example of apparatus used to calibrate a direction of flux sprayed from a nozzle in a fluxing process; and

FIG. 6 illustrates a third example of apparatus used to calibrate an amount and/or direction of flux sprayed from a nozzle in a fluxing process.

### DESCRIPTION

The illustrative examples relate to methods of calibrating an amount and a direction of flux sprayed by a dropjet, or nozzle, in a fluxing process.

The methods of calibration are intended for use in a selective soldering machine. However, the methods of calibration can be used with any soldering machine. Otherwise, the methods of calibration may be performed separately to the soldering machine, for example before the fluxing process is implemented, and then the calibration used to improve the fluxing process.

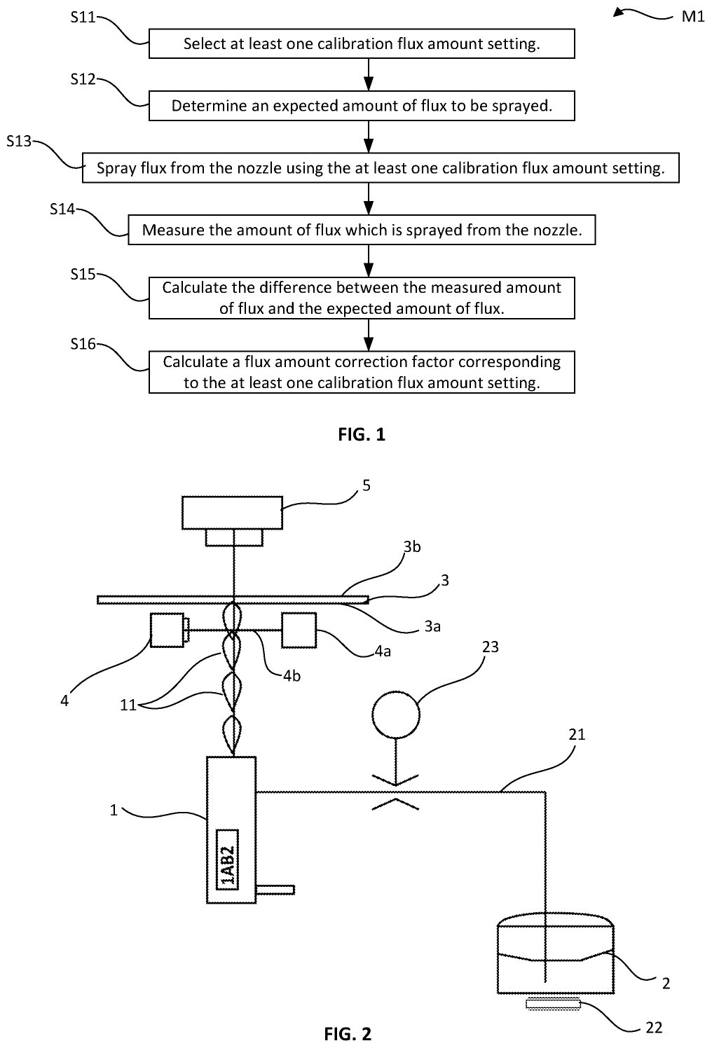

Referring to FIG. 1, there is shown a flowchart illustrating a method M1 of calibrating an amount of flux sprayed by a nozzle 1 in a fluxing process in a soldering machine.

At a first step S11 of the method M1, at least one calibration flux amount setting is selected. The at least one calibration flux amount setting may be at least one calibration pressure setting for a flux tank, the flux tank being a tank which stores flux and provides flux to the nozzle 1.

The at least one calibration flux amount setting may also or alternatively be at least one calibration open time setting, which is an amount of time for which flux is sprayed from the nozzle 1. The at least one calibration open time setting may account for an absolute open time of the nozzle 1. The at least one calibration open time setting may also account for the frequency with which the nozzle is opened. For example, the at least one calibration open time setting may be a total amount of time for which the nozzle 1 remains open over a time period.

In this example the at least one calibration flux amount setting is selected via calibration circuitry. The calibration circuitry may be a part of soldering machine control circuitry. The calibration circuitry may comprise processing circuitry which implements a calibration program. The calibration circuitry may comprise memory circuitry. The memory circuitry is configured to store any number of the parameters used in the calibration program. The calibration program may automatically select the at least one calibration flux amount setting, or the at least one calibration flux amount setting may be entered into the calibration circuitry manually.

In a second step S12 an expected amount of flux to be sprayed from the nozzle 1 is determined. When the at least one calibration flux amount setting is at least one calibration open time setting, the expected amount of flux sprayed from the nozzle 1 when the nozzle 1 is open for a duration equivalent to the at least one calibration open time setting, is determined. When the at least one calibration flux amount setting is at least one calibration flux tank pressure setting, the expected amount of flux sprayed from the nozzle 1 when the tank pressure is set to the at least one calibration tank pressure, is determined.

In this example the expected amount of flux is determined by the calibration circuitry. The expected amount of flux may be determined by the calibration circuitry using a lookup table, where calibration flux amount settings are provided with corresponding expected flux amounts. Calibration flux amount settings and corresponding expected flux amounts may be provided correspondingly to the type of flux and/or the type of nozzle 1, and/or any other upstream settings. Alternatively, or additionally, the expected amount of flux may be determined by the calibration circuitry using an algorithm. The at least one calibration flux amount setting may provide an input to the algorithm. Other parameters entered into the algorithm may include parameters relating to the flux type and/or nozzle type.

In a third step S13, flux is sprayed from the nozzle 1 using the at least one calibration flux amount setting.

In a fourth step S14, the amount of flux sprayed from the nozzle 1 is measured. In this example, the measurement of the amount of flux sprayed is sent to the calibration circuitry, for example to be stored in the memory circuitry.

In a fifth step S15, a difference between the measured amount of flux and the expected amount of flux is calculated. In this example the difference is calculated by the calibration circuitry.

In a sixth step S16, a flux amount correction factor is calculated using the difference between the measured amount of flux and the expected amount of flux. In this example, the flux amount correction factor is calculated by the calibration circuitry. The flux amount correction factor is applicable to the soldering machine, during a fluxing process, to reduce the difference between the sprayed amount of flux and the expected amount of flux. For example, if the sprayed amount of flux is greater than the expected amount of flux, then the duration for which the nozzle is open for may be reduced, and/or the flux tank pressure may be reduced, by a factor corresponding to the flux amount correction factor. On the contrary, if the sprayed amount of flux is less than the expected amount of flux, then the duration for which the nozzle is open for may be increased, and/or the flux tank pressure maybe be increased, by a factor corresponding to the flux amount correction factor.

The at least one calibration flux amount setting may comprise a plurality of calibration flux amount settings. The method M1 may be performed for each of the plurality of calibration flux amount settings, such that a plurality of flux amount correction factors are determined, which correspond to the plurality of calibration flux amount settings or to the expected amounts of flux for the respective calibration flux amount settings. The soldering machine control circuitry may then use the plurality of flux amount correction factors during fluxing processes. For example, when the flux amount correction factors are open time correction factors, one of the open time correction factors may be applied to the nozzle open time, during a fluxing process, by looking up the corresponding open time correction factor to be applied to the open time of the nozzle, to achieve the expected amount of flux sprayed from the nozzle 1 (i.e. to match an actual amount of flux to the expected, or required, amount of flux). As such, a corrected nozzle open time, incorporating the nozzle open time and the corresponding correction factor, is determined. Looking up the corresponding flux amount correction factor may comprise interpolation between adjacent flux amount correction factors and expected amounts of flux.

Referring now to FIG. 2, there is shown an example of an apparatus, which can be used to implement the method M1 of calibrating an amount of flux sprayed by the nozzle 1 in a fluxing process in a soldering machine. In this example flux is pumped from a flux storage tank 2. The flux flows from the flux storage tank 2, through a flux supply line 21, to the nozzle 1. In this example the flux is sprayed from the nozzle 1 as droplets 11.

In this example the amount of flux sprayed from the nozzle 1 is controlled by either, or both, of the open time of the nozzle 1 or the pressure of the flux storage tank 2, as selected at the first step S11 of the method M1 for calibrating the amount of flux sprayed by the nozzle 1. The nozzle has an opening frequency which relates to the frequency with which the nozzle 1 is opened, to spray flux, and is then closed, to prevent the spraying of flux. When the amount of flux is at least partially controlled by the open time of the nozzle 1, the opening time may relate to the duration that the nozzle is opened every time, in that the opening time defines an amount of time that the nozzle remains open without being closed. Otherwise, the opening time may define the total duration for which the nozzle is open over a defined period of time (for example over a succession of open durations according to the frequency).

The flux may be sprayed from the nozzle 1 towards a calibration surface 3, at the third step S13 of the method M1. The calibration surface 3 has a first side 3a, and a second side 3b. The first side 3a faces the nozzle 1. The droplets 11 of flux are sprayed onto the first side 3a. The second side 3b faces away from the nozzle 1. The calibration surface 3 may be paper. However, it will be appreciated that any suitable material may be used. The calibration surface 3 may be absorbent, transparent or translucent, such that flux which is sprayed onto the first side 3a is visible from the second side 3b.

The amount of flux sprayed from the nozzle is measured at the fourth step S14 of the method M1. The amount of flux flowing from the tank 2 to the nozzle 1 may be measured using scales 22 to measure the change in mass of the flux storage tank 2. Alternatively, or additionally, the amount of flux may be measured using a flow meter 23. In this example the flow meter 23 measures the mass flow rate of flux flowing through the flux supply line 21. Alternatively, or additionally, the amount of flux sprayed from the nozzle may be measured using an optical sensor 4. The optical sensor may be of any suitable type for measuring the flow of fluid. For example, the optical sensor 5 may be a laser sensor, such as a laser fork sensor. The optical sensor 4 may have a reflection portion 4a, which, for example, reflects laser light. In this example, the optical sensor 4 measures the amount of time for which a droplet 11 of flux passes through a line of sight 4b of the optical sensor 4. Alternatively, or additionally, the amount of flux may be measured using an optical device 5, which in this example is a camera, and which views the second side 3b of the calibration surface 3. The optical device 5 measures the amount of flux spreading on the calibration surface 3, which provides an indication of the amount of flux which is sprayed onto the surface.

The calibration circuitry uses measurements of the amount of flux sprayed to determine the at least one flux amount correction factor at the sixth step S16 of the method M1. The amount of flux sprayed, as measured using the optical sensor 4 and/or the optical device 5, may also be compared with the amount of flux flowing from the tank 2 to the nozzle 1, as measured using the flow meter 23 and/or the scales 22. If more flux flows from the tank 2 to the nozzle 1 than is sprayed onto the calibration surface 3, then there is likely to be degradation or a blockage of the nozzle 1. The amount of flux spreading, as measured using the optical device 5, may also be used to assess the temperature and/or consistency of the flux. The optical sensor 4 may also enable a verification that the open time and frequency of the nozzle 1 are correct, and/or provide an alarm or an alert if they are incorrect.

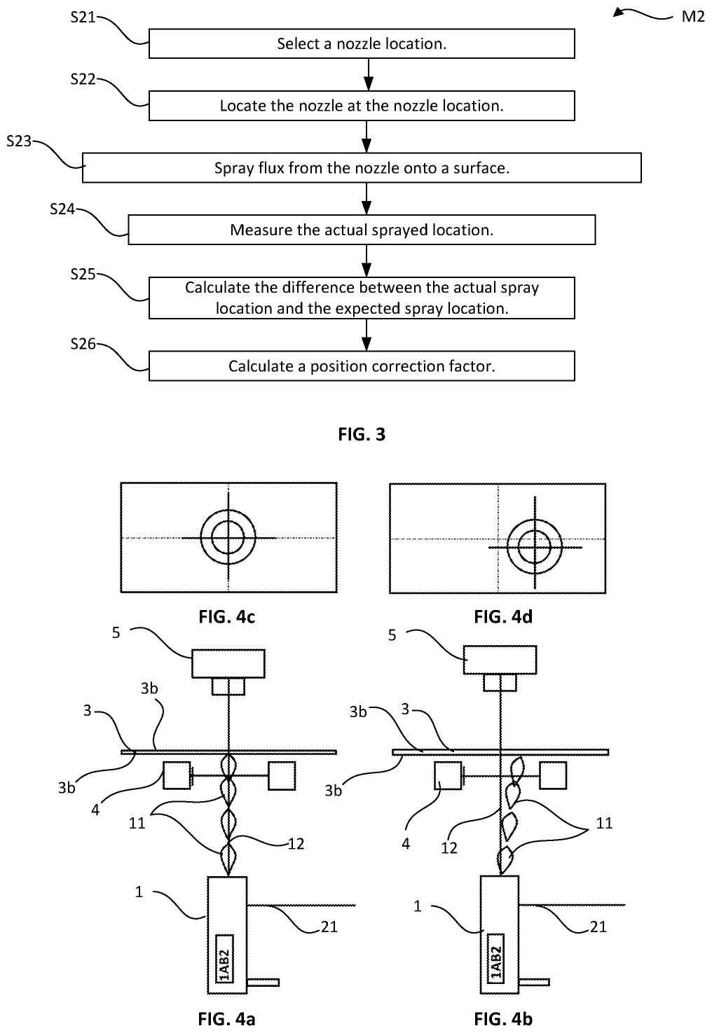

Referring to FIG. 3, there is shown a flowchart illustrating a method M2 of calibrating a direction of flux sprayed by the nozzle 1 in a fluxing process in a soldering machine.

In a first step S21 of the method M2 a nozzle location is selected. The nozzle location is selected such that flux sprayed onto a calibration surface 3 by the nozzle 1 when the nozzle 1 is located at the nozzle location, is expected to have a centre at an expected spray location. In this example the nozzle location is selected via calibration circuitry, which may be the same calibration circuitry used in the flux amount calibration method M1. The calibration circuitry may automatically select the nozzle location, or the nozzle location may be entered into the calibration circuitry manually. In this example the nozzle location is a location on a plane, wherein the plane is parallel to the calibration surface 3.

In a second step S22 the nozzle 1 is located at the nozzle location. In a third step S23 flux is sprayed from the nozzle 1. In this example the flux is sprayed from the nozzle 1, onto the calibration surface 3, for a predetermined amount of time. The period of time for which flux is sprayed form the nozzle 1 may be controlled by the calibration circuitry or the solder machine control circuitry.

In a fourth step S24, the actual spray location is measured. In this example, the actual spray location is measured as the centre of the sprayed flux on the surface. The centre of the sprayed flux may be measured as the geometric centre of the sprayed flux. In this example the actual spray location is recorded by the calibration circuitry.

In a fifth step S25 the difference between the expected spray location and the actual spray location is measured. The difference may include a distance component and a direction component. In this example, the difference is calculated by the calibration circuitry.

In a sixth step S26 a position correction factor is calculated. In this example the position correction factor is calculated by the calibration circuitry. The position correction factor is applicable to the nozzle during a fluxing process to reduce the difference between the expected spray location and the actual spray location. In this example the position correction factor is applied to the position of the nozzle 1 in the plane which is parallel to the calibration surface 3. The position correction factor may be applied to the position of the nozzle 1 to provide a corrected nozzle position such that, when the nozzle 1 sprays flux from the corrected position, the difference between where the flux is sprayed, and the expected spray location, is minimised. During a fluxing process, the solder machine control circuitry may select an expected flux spray location and determine the nozzle location which corresponds to the expected flux spray location. The position correction factor may then be applied to the nozzle location, such that the difference between the actual flux spray location and the expected flux spray location is minimised.

Referring now to FIGS. 4a and 4b, there is shown an example of apparatus which can be used to implement the method M2 for calibrating the direction of flux sprayed by the nozzle 1 in a fluxing process in a soldering machine. The apparatus is the same or similar to that described with reference to FIG. 2, and like features are denoted with the same reference numerals.

In this example the droplets 11 of flux are sprayed onto the calibration surface 3. The calibration surface 3 may be the same calibration surface 3 as described with reference to FIG. 2.

In the apparatus shown in FIGS. 4a & 4b, the optical device 5 measures the location of the flux sprayed onto the calibration surface 3. In FIG. 4a the droplets 11 of flux are sprayed along a nozzle axis 12, which is perpendicular to the calibration surface 3. When droplets 11 of flux are sprayed along the nozzle axis 12 there is substantially no deviation. Therefore, the flux is sprayed onto the expected location on the calibration surface 3, and so the position correction factor, as calculated in the sixth step S26 of the method M2, is substantially zero. In the example shown in FIG. 4b, there is deviation on the direction with which the flux is sprayed from the nozzle 1, and so the droplets 11 of flux deviate from the nozzle axis 12. Therefore, in the apparatus shown in FIG. 4b, there will be a position correction factor calculated in the sixth step S26 of the method M2.

Referring now to FIGS. 4c and 4d there is shown a schematic of the second side 3b of the calibration surface 3 in each of the apparatus shown in FIG. 4a and FIG. 4b respectively, as viewed by the optical device 5. The expected flux spray location is shown by the intersection of the dash-dot lines. On the calibration surface 3 shown in FIG. 4c, the centre of the sprayed flux overlays the expected flux location, and so the position correction factor is substantially zero. On the calibration surface 3 shown in FIG. 4d, the centre of the sprayed flux is offset from the expected flux location. Therefore, the position correction factor will include a vector containing a magnitude and direction between the centre of the sprayed flux, and the expected flux spray location.

The method M1 for calibrating an amount of flux, and the method M2 for calibrating the direction of flux may be combined to provide a method of calibrating the nozzle 1 for use in the fluxing process in the soldering machine. The apparatus shown in FIG. 2 and in FIGS. 4a & 4b may be combined, such that the method of calibrating the nozzle 1 can be implemented.

Advantageously, the aforementioned calibration methods M1, M2 may allow minor adjustments to the amount of flux sprayed and the position of the nozzle 1, when, for example, there is minor degradation of the nozzle 1, or if the nozzle requires cleaning. The methods M1, M2 may be performed multiple times during processing, to monitor the performance of the nozzle 1, to delay cleaning, repair, or replacement, until this is necessary. The methods M1, M2 may also be used to predict the lifecycle of the nozzle 1.

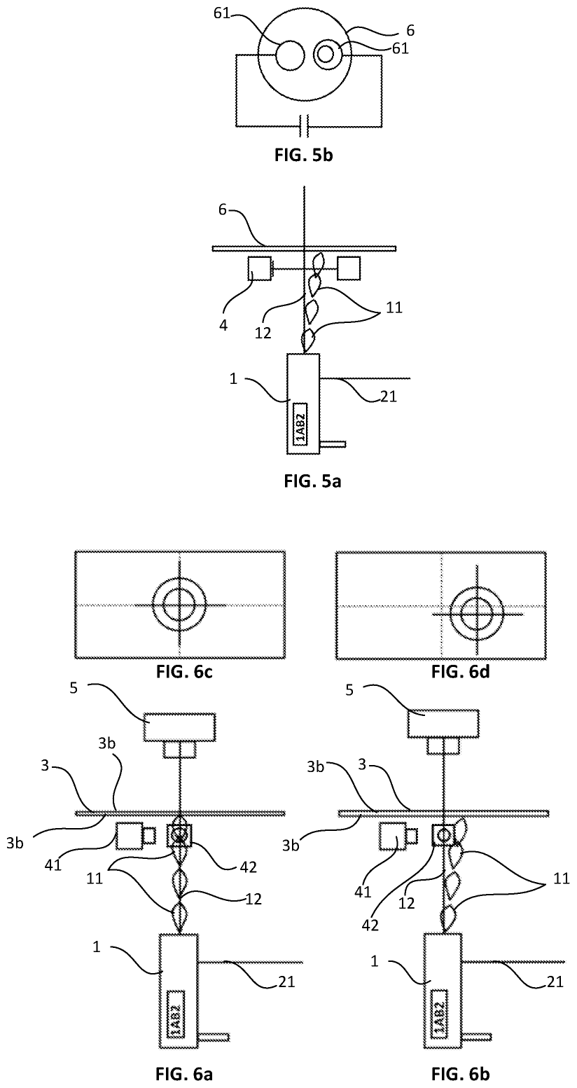

Referring to FIGS. 5a & 5b there is shown another example of apparatus which can be used in the implementation of the method M2 of calibrating a direction of flux sprayed by the nozzle 1 in a fluxing process in a soldering machine. The apparatus is the same as that described with reference to FIGS. 4a & 4b, with the exception that the calibration surface 3 comprises a flux sensor 6. The flux sensor 6 comprises at least two conductive pads 61. When flux is sprayed without deviation from the nozzle 1 along the nozzle axis 12, the flux bridges the two conductive pads and completes an electrical circuit. This completed electrical circuit may then be identified by the calibration circuitry, to indicate that there is no deviation of flux. If the flux direction deviates from the nozzle axis 12, then the flux will not bridge the gap between the conductive pads 61. An example of such a deviation is shown in FIGS. 5a and 5b, wherein, in FIG. 5b, the flux is located upon the right-hand conductive pad 61 only.

In any of the aforementioned apparatus the optical sensor 4 may also provide a measurement of an amount of deviation of the flux from the nozzle axis 12. For example, if the optical sensor 4 is a laser fork, then the reflection time of the laser may be used to calculate the distance of each droplet 11 of flux away from the nozzle axis 12. The optical sensor 4 may comprise two laser forks which are in the same plane, but which are orientated at substantially 90° to one another. In this way, the deviation of the droplets 11 of flux in both Cartesian coordinates in the plane of the laser forks, may be determined. As the distance of the optical sensor 4 from the flux sensor 6 is known, the measurement(s) of deviation from the nozzle axis 12 can be used to measure the actual spray location in the fourth step S24 of the method M2.

Referring now to FIGS. 6a-6d there is shown another example of apparatus which can be used to implement the method M1 for calibrating the amount of flux sprayed by the nozzle 1 and the method M2 for calibrating the direction of flux sprayed by the nozzle 1 in a fluxing process in a soldering machine. The apparatus is similar to the aforementioned apparatus, and like features are denoted with the same reference numerals. The apparatus of FIGS. 6a-6d differs from previously described apparatus in that the optical sensor is a high-speed camera 41. The high-speed camera 41 can be used to count the amount and/or size of droplets of flux, and thereby implement the method M1 of calibrating the amount of flux sprayed by the nozzle 1.

A second high speed camera 42 may also be provided at an oblique angle to the first high-speed camera 41. By providing two high-speed camera 41, 42 images of the flux being sprayed from the nozzle 1 are captured and processed by the processing circuitry to determine the deviation of the flux as it is sprayed from the nozzle 1 can be captured. This deviation is then used to provide the measurement of the actual spray location in the fourth step S24 of the method M2.

In the example of FIGS. 6a-6d Figure 6 the optical device 5 can be used to provide a measurement of the amount of flux spreading, as described previously. Otherwise, the high-speed cameras 41, 42 may only be used to measure the deviation of flux spraying, and the optical device 5 may be used to measure the amount of flux sprayed, as described previously and as per step S14 in method M1. Otherwise, the high-speed camera 41 may be used to measure the amount of flux sprayed, and the optical device 5 may be used to measure the actual sprayed location, as per step A24 in method M2. Otherwise, both the high-speed cameras 41, 42 and the optical device 5 may be used to measure the amount of flux sprayed and the actual spray location. In this case, these measurements can be used to identify measurement errors by calculating the difference between each measured value.

In another example the high-speed camera 41 is provided in an apparatus which also comprises the flux sensor 6 of FIG. 5. In this example the high-speed camera 41 is used to measure the amount of flux sprayed and the flux sensor 6 is used to measure the actual spray location. A second high-speed camera 42 may also be provided to provide a second actual flux spray location measurement, alongside that obtained using the flux sensor 6.

In a further example, the apparatus described with reference to FIGS. 3, 4a, 4b and 5a are combined such that the flux sensor 6 indicates if there is deviation in the flux spray direction from the nozzle 1, and the optical device 5 measures the difference between the expected spray location and the measured spray location and the amount of flux spreading. The calibration surface 3 may be provided after a deviation has been detected by the flux sensor 6, and the flux sprayed again, such that the optical device 5 can be used to measure the actual spray location and the amount of flux. Otherwise, an absorbent, transparent, or translucent flux sensor 6 may be used, such that the optical device 5 can measure the actual spray location and the amount of flux sprayed on the flux sensor 6.

In all of the aforementioned apparatus examples the nozzle 1 may be identified using an identifier located on the nozzle 1, or dropjet. The identifier may comprise radio-frequency identification (RFID). The identifier may be read by the calibration circuitry. The identifier may provide information, or provide the location of information on a server, the information relating to the nozzle 1. The information relating to the nozzle 1 may include, for example, a size, a type, power parameters, the age, a cleaning history, or a maintenance history.

In a further example, there is provided a method of monitoring and/or maintaining the nozzle 1. Monitoring circuitry may monitor the at least one flux amount correction factor, and/or the at least one position correction factor and/or the amount of flux spreading. The monitoring circuitry may be a part of the calibration circuitry. The monitoring circuitry may be a part of the solder machine control circuitry. The monitoring circuitry may monitor the at least one flux amount correction factor and/or the at least one position correction factor and/or the amount of flux spreading to identify trends, which may indicate the degradation, for example a blockage, of the nozzle 1. The monitoring circuitry may monitor the at least one flux amount correction factor, the at least one position correction factor and/or the amount of flux spreading to identify trends, which may indicate a requirement for cleaning of the nozzle 1. The monitoring circuitry may calculate an expected life of the nozzle 1. The monitoring circuitry may schedule maintenance of the nozzle, for example for cleaning, repair, or replacement. The monitoring circuitry may monitor the at least one flux amount correction factor, the at least one position correction factor and/or the amount of flux spreading to identify a problem with the flux. A problem with the flux may be, for example, an incorrect flux temperature or an incorrect flux consistency. The monitoring circuitry may provide information and/or alerts to the user. Advantageously, this means that the soldering machine may be monitored without requiring downtime, as monitoring occurs during calibration. The monitoring circuitry may provide a predictive maintenance algorithm, to predict the lifecycle of components any of the aforementioned apparatus.

In a further example there is provided a cleaning routine for the nozzle 1. The cleaning routine may be initiated by the monitoring circuitry. The cleaning routine may be initiated in response to the trends identified from monitoring the at least one flux amount correction factor, the at least one position correction factor and/or the amount of flux spreading. The cleaning routine may comprise spraying flux from the nozzle 1 at varying frequencies and/or open times. The cleaning routine may comprise using cleaning alcohol to clean the nozzle 1. After the cleaning routine has been implemented, one or more of the calibration methods may be performed, to verify the effectiveness of the cleaning routine. If the one or more calibration methods provide unsatisfactory results, the cleaning routine may be implemented again. Otherwise, further maintenance may be implemented.

Whilst in the aforementioned specific examples the methods are for calibrating a parameter in a fluxing process in a soldering machine, where the parameter is either an amount of flux sprayed by a nozzle or a direction of flux sprayed by the nozzle, the parameter may be any parameter which is used for a fluxing process in a soldering machine.

The following numbered clauses are provided:
Clause 1. A method of calibrating a parameter in a fluxing process in a soldering machine, the method comprising the steps of:
   determining an expected flux result when at least one calibration flux setting is used to spray flux from a nozzle;
   spraying flux from the nozzle using the at least one calibration flux setting;
   measuring the obtained flux result when flux is sprayed using the at least one calibration flux setting;
   calculating the difference between the measured flux result and the expected flux result; and
   calculating a flux result correction factor corresponding to the at least one calibration flux setting, wherein the correction factor is applicable to the soldering machine during a fluxing process, to reduce the difference between the sprayed flux result and the expected flux result.
Clause 2. A method according to clause 1, wherein the at least one calibration flux setting is at least one calibration flux amount setting, the parameter is an amount of flux sprayed by a nozzle, the expected flux result is an expected flux amount, the obtained flux result is an amount of flux sprayed, and the flux result correction factor is a flux amount correction factor corresponding to the at least one calibration flux amount setting, wherein the correction factor is applicable to the soldering machine during a fluxing process, to reduce the difference between the sprayed amount of flux and the expected amount of flux.
Clause 3. A method according to clause 2, wherein the at least one calibration flux amount setting is at least one calibration open time setting, the open time setting defining the duration for which the nozzle is open.
Clause 4. A method according to clause 3, wherein the correction factor is applied to an operational open time of the nozzle during the fluxing process.
Clause 5. A method according to clause 2, wherein the at least one calibration flux amount setting is at least one calibration flux tank pressure setting, the flux tank containing the flux which is fed to the nozzle.
Clause 6. A method according to clause 5, wherein the correction factor is applied to an operational flux tank pressure during the fluxing process.
Clause 7. A method according to any of clauses 2 to 6 where the amount of flux sprayed from the nozzle is measured by measuring the amount of flux spreading onto a surface onto which the flux is sprayed.
Clause 8. A method according to clause 7, wherein the amount of flux spreading is measured using an optical device, for example a camera.
Clause 9. A method according to clause 1, wherein the at least one calibration flux setting is a nozzle location, such that flux sprayed onto a surface by the nozzle when the nozzle is located at the nozzle location is expected to have a centre at the expected spray location, and wherein the parameter is a direction of flux sprayed by the nozzle, the expected flux result is the expected spray location, the obtained flux result is an actual spray location, which is measured by locating the centre of the sprayed flux on the surface, and the flux result correction factor is at least one position correction factor, wherein the position correction factor is applicable to the nozzle location during a fluxing process to reduce the difference between the expected spray location and the actual spray location.
Clause 10. A method of calibrating a nozzle for use in a fluxing process in a soldering machine, the method comprising the steps of:
   calibrating the amount of flux sprayed by a nozzle using a method according to any one of clauses 2 to 8; and
   calibrating the direction of flux sprayed by the nozzle using a method according to clause 9.
Clause 11. A method according to either of clause 9 or 10, wherein the surface is paper.
Clause 12. A method according to any of clause 9 to 11, wherein the actual spray location is located using a camera.
Clause 13. A method of monitoring the performance of a soldering machine, the method comprising monitoring correction factors calculated in any preceding clause.
Clause 14. A method according to any preceding clause, wherein the flux amount correction factor and/or the at least one position correction factor and/or the amount of flux spreading are/is used to determine if the nozzle requires maintenance or cleaning.
Clause 15. A method according to clause 14, wherein the method includes performing a cleaning routine with the nozzle, the cleaning routine comprising spraying flux from the nozzle at varying frequency and/or applying cleaning alcohol to the nozzle.

1-28. (Canceled)

29. A method of calibrating a parameter in a fluxing process in a soldering machine, the method comprising:
determining an expected flux result when at least one calibration flux setting is used to spray flux from a nozzle;
spraying flux from the nozzle using the at least one calibration flux setting;
measuring the obtained flux result when flux is sprayed using the at least one calibration flux setting;
calculating the difference between the measured obtained flux result and the expected flux result; and
calculating a flux result correction factor corresponding to the at least one calibration flux setting, wherein the flux result correction factor is applicable to the soldering machine during a fluxing process, to reduce the difference between the sprayed flux result and the expected flux result.

30. The method according to claim 29, wherein the at least one calibration flux setting comprises at least one calibration flux amount setting, the parameter comprises an amount of flux sprayed by a nozzle, the expected flux result comprises an expected flux amount, the measured obtained flux result comprises an amount of flux sprayed, and the flux result correction factor comprises a flux amount correction factor corresponding to the at least one calibration flux amount setting, wherein the flux amount correction factor is applicable to the soldering machine during a fluxing process, to reduce the difference between the sprayed amount of flux and the expected amount of flux.

31. The method according to claim 30, wherein the at least one calibration flux amount setting comprises at least one calibration open time setting, the calibration open time setting defining the duration for which the nozzle is open.

32. The method according to claim 31, wherein the flux amount correction factor is applied or is applicable to an operational open time of the nozzle during the fluxing process.

33. The method according to claim 30, wherein the at least one calibration flux amount setting comprises at least one calibration flux tank pressure setting, the flux tank containing the flux which is fed to the nozzle.

34. The method according to claim 33, wherein the flux amount correction factor is applied or is applicable to an operational flux tank pressure during the fluxing process.

35. The method according to claim 30, where the amount of flux sprayed from the nozzle is measured by measuring the amount of flux spreading onto a surface onto which the flux is sprayed.

36. The method according to claim 35, wherein the amount of flux spreading is measured using an optical device.

37. The method according to claim 30, wherein the amount of flux sprayed from the nozzle is measured using an optical sensor, for example a laser fork sensor or a high-speed camera.

38. The method according to claim 29, wherein the at least one calibration flux setting comprises a nozzle location, such that flux sprayed onto a surface by the nozzle when the nozzle is located at the nozzle location is expected to have a center at an expected spray location, and wherein the parameter comprises a direction of flux sprayed by the nozzle, the expected flux result comprises the expected spray location, the obtained flux result comprises an actual spray location, which is measured by locating the center of the sprayed flux on the surface, and the flux result correction factor comprises at least one position correction factor, wherein the at least one position correction factor is applied or is applicable to the nozzle location during a fluxing process to reduce the difference between the expected spray location and the actual spray location.

39. A method of calibrating a nozzle for use in a fluxing process in a soldering machine, the method comprising the steps of:
calibrating the amount of flux sprayed by a nozzle using the method according to claim 38; and
calibrating the direction of flux sprayed by the nozzle using the method according to claim 38.

40. The method according to claim 38, wherein the surface is paper.

41. The method according to claim 38, wherein the actual spray location is located using a camera.

42. The method according to claim 38, wherein the actual spray location is located by measuring the deviation of spray from the nozzle using at least two high-speed cameras.

43. A method of monitoring the performance of a soldering machine, the method comprising monitoring at least one of the flux result correction factor or the position correction factor calculated according to claim 38.

44. The method according to claim 43, wherein at least one of the flux amount correction factor, the at least one position correction factor, or the amount of flux spreading are used to determine if the nozzle requires maintenance or cleaning.

45. The method according to claim 44, further comprising performing a cleaning routine with the nozzle, the cleaning routine comprising at least one of spraying flux from the nozzle at varying frequency or applying cleaning alcohol to the nozzle.

46. A flux nozzle calibration apparatus for calibrating a parameter of a flux nozzle, the flux nozzle being for use in a soldering machine, the apparatus comprising:
at least one sensor configured to measure an obtained flux result when flux is sprayed from a nozzle using at least one calibration flux setting; and
processing circuitry configured to:
calculate the difference between the measured obtained flux result and an expected flux result; and
calculate a flux result correction factor corresponding to the at least one calibration flux setting, wherein the flux result correction factor is applicable to the soldering machine during a fluxing process, to reduce the difference between the sprayed flux result and the expected flux result.

47. The flux nozzle calibration apparatus of claim 46, further comprising memory circuitry configured to store any number of:
the parameter of a flux nozzle:
the measured obtained flux result;
the expected flux result;
the at least one calibration flux setting; and
the flux result correction factor corresponding to the at least one calibration flux setting.

48. The flux nozzle calibration apparatus of claim 47, further comprising a calibration surface which is configured to receive the flux which is sprayed from the nozzle.
